(19) United States
(12) Patent Application Publication
(10) Pub. No.: US 2012/0092012 A1
(43) Pub. Date: Apr. 19, 2012

(54) SHAPED CARBON NANOMATERIAL IMAGING COIL ELEMENTS FOR MAGNETIC RESONANCE IMAGING

(76) Inventor: Raju Viswanathan, St. Louis, MO (US)

(21) Appl. No.: 12/905,031

(22) Filed: Oct. 14, 2010

(51) Int. Cl. G01R 33/44

(52) U.S. Cl. 324/318

(57) ABSTRACT

MRI imaging coil elements can include at least one electrical conductor formed from shaped carbon-based nanomaterial, the carbon-based nanomaterial conductor having a ratio of electrical inductive reactance to electrical resistance, over a range of frequencies, that is larger than that of a similarly dimensioned electrical conductor constructed only of metal, and a connector coupled to the first electrical conductor for functionally connecting the imaging coil element to electronic circuitry connecting to a magnetic resonance imaging system. The shape of the carbon-based nanomaterial in at least one of the imaging coil elements formed from carbon-based nanomaterial can be selected from a yarn-like shape, a ribbon-like shape, and a string-like shape. Similarly, the carbon-based nanomaterial in the at least one imaging coil element formed from carbon-based nanomaterial is structured as one of, carbon nanotubes, Buckypaper, and graphene.

### FIELD

This application relates generally to diagnostic medical imaging, and more specifically to magnetic resonance imaging (MRI) with shaped carbon nanomaterial imaging coil elements.

### BACKGROUND

MRI technology as a diagnostic imaging modality has led to huge benefits to modern medical science and practice. A significant factor affecting the further increased use of this versatile imaging technology is the image quality that can be obtained with a given MR scanner system in a reasonable time that does not adversely impact patient comfort.

The image quality of MRI is influenced by several factors. An important factor is the SNR associated with the signal acquisition process and in particular with the signal acquisition/imaging coils employed in Radio Frequency (RF) signal reception. Higher levels of SNR may usually be traded off for increased image resolution and/or reduced scan time. Currently imaging coils are constructed from a highly conductive metal, usually copper, and each type of coil is designed for reasonably optimal performance in its respective clinical application. The trend over the last several years has been to increasingly move towards arrays of individual coil elements, as there is generally an inverse relation between the SNR and coil dimensions. Typically, however, this increased SNR comes at the price of decreased depth of penetration, so that several or many array elements may be needed to cover the entire volume of interest with a reasonably high SNR.

Furthermore, the SNR of a coil is limited by the electrical resistance associated with the coil, and more specifically by the effective resistance to induced current flow in both the coil and the tissue of interest (respectively referred to often as coil resistance and body resistance). The SNR is also limited by how much signal energy is contained relative to noise within the bandwidth of interest around the center frequency associated with the scanner magnet. In the case of arrays of coil elements, inductive coupling between the coil elements can act to further reduce SNR and the design of the array needs to take into consideration such mutual interactions.

### SUMMARY

MRI that uses formed nanomaterial imaging coil elements with high intrinsic SNR are disclosed that can offer advantages in the design of highly effective imaging coils and coil arrays that also can yield high SNR. Methods of coil design and construction are disclosed that take advantage of the electrical properties of low resistance and high gain imaging coils or coil elements formed using carbon-based nanomaterials. Imaging coil elements for magnetic resonance imaging can include at least one electrical conductor formed from shaped carbon-based nanomaterial, the carbon-based nanomaterial conductor having a ratio of electrical inductive reactance to electrical resistance, over a range of frequencies, that is larger than that of a similarly dimensioned electrical conductor constructed only of metal, and a connector coupled to the first electrical conductor for functionally connecting the imaging coil element to electronic circuitry connecting to a magnetic resonance imaging system. Imaging coil elements can have range of radio frequencies is between about 3 MHz and 700 MHz.

The shape of the carbon-based nanomaterial in at least one of the imaging coil elements formed from carbon-based nanomaterial can be selected from a yarn-like shape, a ribbon-like shape, and a string-like shape. Similarly, the carbon-based nanomaterial in the at least one imaging coil element formed from carbon-based nanomaterial is structured as one of, carbon nanotubes, Buckypaper, and graphene.

Imaging coil elements can be one element in an imaging coil array used for at least one of transmission or reception of radio frequency signals. The nanomaterial conductors can have metalized ends, at least one of the metalized ends acting as a connector and including at least one electrical connection providing an electrical conduction pathway with the nanomaterial conductor.

The imaging coil elements can be connectable to electronic tuning and matching circuitry to create an electrically resonant structure near a frequency of interest. Similarly, the electronic tuning and matching circuitry can include a preamplifier for augmenting signal gain.

In other embodiments, an imaging coil for an MRI system can include a plurality of imaging coil elements, at least one of the plurality of imaging coil elements being formed from shaped carbon-based nanomaterial, each of the at least one imaging coil element formed from carbon-based nanomaterial, the nanomaterial having a ratio of electrical inductive reactance to electrical resistance for the imaging coil element, over a range of frequencies, that is larger than that of a similarly dimensioned imaging coil element constructed only of metal. The imaging coil elements can include a metal conducting connector deposited on at least one end of each of the imaging coil elements for electrically coupling the imaging coil to an MRI system.

The imaging coil can have a known spatial signal sensitivity profile and is adapted to be utilized in the image reconstruction process with data from radio frequency signals received by the imaging coil to reconstruct an anatomical image of a desired region of interest in a subject being imaged. The imaging coil element can be formed from carbon-based nanomaterial and can have a larger quality factor than that of a coil element of similar form factor constructed with only metallic electrical conductors.

Also, the transmit power requirement for a given radio frequency pulse sequence for the at least one imaging coil element formed from carbon-based nanomaterial while transmitting radio frequency energy can be at least ten per cent smaller than the transmit power requirement for the same radio frequency pulse sequence for an imaging coil element of similar form factor formed with only metallic electrical conductors. While the at least one imaging coil element formed from carbon-based nanomaterial is transmitting radio frequency energy, the Specific Absorption Rate for a given tissue type and given radio frequency pulse sequence is at least ten per cent smaller than the Specific Absorption Rate for the same tissue type and radio frequency pulse sequence for an imaging coil element of similar form factor formed with only metallic electrical conductors.

### BRIEF DESCRIPTION OF THE DRAWINGS

The following description can be better understood in light of Figures, in which:

FIG. 1 is a schematic illustration of a nanomaterial conductor with metallized ends and in the form of a twisted or braided thread;

FIG. 2 is a schematic illustration of a nanomaterial conductor with metallized ends and in the form of a ribbon-like geometry;

FIG. 3 is a schematic illustration of a nanomaterial conductor with metallized ends and in the form of an aggregated nanomaterial conductor in the form of a bundle of individual nanomaterial conductors;

FIG. 4 is a schematic illustration of a nanomaterial conductor with metallized ends attached to a metallic conductor;

FIG. 5 is a schematic illustration of a composite nanomaterials conductor in the form of two layers including a nanomaterial conductor;

FIG. 6 is a schematic illustration of a nanomaterial conductor with metallized attached to a metallic conductor that is folded;

FIG. 7 is a schematic illustration of a nanomaterial conductor with metallized ends attached at the metalized ends to a hollow metallic tube;

FIGS. 8 and 9 are schematic illustrations of an imaging coil element having a generally rectangular geometry mounted on a base or substrate and connected to a circuit board with tuning and matching circuitry;

FIG. 10 is a schematic illustration of an imaging coil element of the present invention having a generally circular geometry; and

FIGS. 11a-12 illustrate various geometries of imaging coil elements of the present invention.

Together with the following description, the Figures demonstrate and explain the principles of nanomaterial imaging coils formed using various nanomaterial configurations and shapes. In the Figures, the size, number and configuration of components may be exaggerated for clarity. The same reference numerals in different Figures represent the same component.

### DETAILED DESCRIPTION

The following description supplies specific details in order to provide a thorough understanding. Nevertheless, the skilled artisan would understand that embodiments of nanomaterial imaging coils and arrays for MRI systems can be implemented and used without employing these specific details. Indeed, exemplary embodiments and associated methods can be placed into practice by modifying the illustrated units and associated methods and can be used in conjunction with any other devices and techniques conventionally used in the industry.

Embodiments of nanomaterial imaging arrays can include at least two RF receiving coil elements each including at least one electrical conductor including a first electrical conductor formed from shaped carbon-based nanomaterial, a conducting connector deposited on at least one end of the first electrical conductor, and connecting the first electrical conductor to a second electrical conductor formed from metal to comprise a hybrid electrical conductor. In some embodiments, the first electrical conductor can have a conducting connector deposited at both of its ends and is electrically connected to the second electrical conductor at both ends, providing parallel paths for electrical conduction. In a preferred embodiment, at least one coil element can be formed directly from an electrical conductor in the form of shaped carbon-based nanomaterial, a conducting connector being deposited on at least one end of this electrical conductor. The first electrical conductor can be formed from carbon nanomaterial in the form of bundles of carbon nanotubes (either single-walled or multi-walled nanotubes or a combination thereof) in the form of sheets, ribbons, wires, ropes, yarns or other configurations, sheets or stacks of graphene, or similar material exhibiting ballistic charge transport characteristics over length scales of about 10 microns or more.

Other examples of materials that could potentially have broadly similar characteristics include buckypaper and carbon nanotube-infused polymers, such as carbon nanotubes interspersed or dispersed in a polymeric film with a suitable degree of connectivity. In the following, the term carbon nanomaterial or carbon-based nanomaterial is understood to be, without limitation, any of the above varieties of nano-structured carbon-based materials or other similar forms with generally similar charge transport characteristics. Similarly, while imaging coils described herein generally include at least one coil element as described herein, more generally, the imaging coil could be one coil of an array of the described coil elements in order to cover a wider/more extensive region of interest in a subject anatomy.

Carbon nanotubes have many interesting electrical, mechanical and thermal properties. Specifically, at appropriate length scales they possess the property of ballistic electron transport, wherein the electrons transported by the conductor do not get significantly scattered over a certain relaxation time interval, such that the electrical resistance offered by the conductor to a current is independent of length over this length scale. In contrast, the resistance of a standard (metallic) electrical conductor increases linearly with length, other things being equal. Furthermore, ballistic conductors do not exhibit a skin effect such that resistance increases with frequency; in fact, in some cases in the MHz frequency range characteristic of MR Imaging, carbon nanotubes demonstrate a weak decreasing dependence of resistance on frequency (for instance, this is discussed in Y. P. Zhao et al, Physical Review B, Volume 64, 2001, p. 201402(R)).

Recently, processes have been developed to fabricate useful lengths of carbon nanotube conductors in the form of thin sheets (M. Zhang et al, Science, Aug. 19, 2005, p. 1215), wires or twisted yarns. Individual thin sheets can be as thin as 50 nanometers; in other forms the effective thickness of the carbon nanomaterial conductor can be no more than a few millimeters while retaining excellent electrical transport properties such as low resistance and high inductance that are advantageous for imaging coils. At radio frequencies of interest to magnetic resonance imaging, a receiving coil comprising such material can have a relatively low intrinsic resistance due to the material's locally ballistic conductance properties and the absence of the skin effect common to metallic (scattering) conductors. In addition the coil can display enhanced inductance properties due to the intrinsic or kinetic inductance associated with a relatively long charge transport relaxation time scale. This combination of properties can yield significant increases in SNR performance even in the presence of body noise or noise arising from resistance to the flow of induced eddy currents in the subject body.

The carbon nanotube conductors can be either Single-Walled Nanotubes or Multi-Walled Nanotubes, methods of construction of both of which are known and described in the literature. While Multi-Walled Nanotubes are employed in the sheet drawing method described in M. Zhang et al, Science, Aug. 19, 2005, p. 1215, for example K. Hata et al, Science, Vol. 306, 19 Nov. 2004, p. 1362, describes a technique for the water-assisted synthesis of Single-Walled Carbon Nanotubes. This technique can provide patterned, highly organized nanotube structures including sheets and pillars and nanotube forests, from which further macroscopic structures such as sheets or films could be fabricated by means of a drawing process. The growth of the initial nanotube structures or forests can often benefit from the presence of catalysts such as Iron nanoparticles together with a suitable substrate such as Silicon. In some cases a suitable doping agent such as Hydrogen can yield further decreases in resistance of sheets drawn from the nanotube forests. The advantages of doping of both Single-Walled Nanotubes and Multi-Walled Nanotubes are described for instance in M. Zhang et al, Science, Aug. 19, 2005, p. 1215. The examples of film or sheet construction methods in the above are discussed for illustrative purposes only. Those skilled in the art can conceive or design alternate fabrication or construction methods without departing from the scope of the present invention.

Electron transport in a material can be phenomenologically described by the Drude model, which models the motion of an electron under the influence of an electric field E caused by a potential gradient in terms of the Drude equation:

m(\ddot{x}+γ\dot{x}+ω₀²x)=−eE (1)

where m is the mass of the electron, (−e) its charge, is a damping constant and the last term on the left is a restoring force on a bound electron. Together with Maxwell's equations and Ohm's law (constitutive equation) for the current density in the form J=E, it can be shown that the above equation can be used to write the resistivity for the material at frequency in the form

$$ρ = \frac{m}{{ne}^{2} τ} ( 1 + iωτ ) \qquad ( 2 )$$

where is the relaxation time and n is the volumetric number density of electrons.

Relaxation time may also be interpreted as the mean time between momentum transfer or scattering events. From equation (2), it is evident that the resistivity has an imaginary part that linearly increases with frequency; this can therefore be physically interpreted as an inductance. It is referred to as kinetic inductance since it arises from the inertia of the charge carriers, in contrast to the usual inductance that arises purely from the geometry of the current distribution. In the case when transport is locally ballistic, as can be the case with carbon-based nanomaterials, the relaxation time can be relatively long, leading to significant contributions to the overall inductance from the kinetic part. At the same time, with sufficiently high density of cross-sectional packing of nanotube bundles, the carbon-based nanomaterial can be made to have low resistance at radio frequencies. As mentioned earlier, this combination of properties can yield significant increases in SNR performance of an imaging coil constructed as disclosed herein.

In some embodiments described in further detail below with reference to the drawings, the carbon nanomaterial in the coil element could be in the form of strings or threads comprising carbon nanotubes or bundles of carbon nanotubes. For example, the carbon nanomaterial could consist of strings or threads comprising carbon nanotubes or nanotube bundles, and possibly incorporating multiple levels of structure, such as braided elements or yarns of such strings, bundles of strings, or ropes comprising braids or bundles of braided elements or yarns. Similarly, the carbon nanomaterial can be in the form of ribbons, stacks or layers of multiple ribbons, or alternatively composites of ribbons and threads or yarns, and may be used as conductive elements on MRI imaging coils, the various shapes providing desired conductive properties for imaging.

The carbon nanomaterial in the coil element can also be used in hybrid conductor form, for example embedded between metallic layers comprising a metallic conductor such as copper. Thus, various sandwich-type constructions of carbon nanomaterial alternating with metallic layers can be used, as also constructions where the carbon nanomaterial can be enclosed within folds of a metallic layer or ribbon, or within hollow metal tubes. In further examples of these hybrid embodiments, the carbon nanomaterial constructed in conjunction with metallic conductors can be in any of the various forms referred to above, such as ribbons, threads, braids, yarns, ropes, or any combination thereof, and can include varieties such as carbon nanotubes interspersed in a paper-like mat or in a polymer matrix, or graphene-based sheets.

For a given electrical conductor geometry or form factor, over a range of radio frequencies of interest covering at least, but not limited to, the low MHz to several hundreds of MHz range, the constructions and embodiments described here can generally be made to yield a larger ratio of inductive reactance to resistance than would be possible for a conductor of comparable overall form factor constructed of metal alone, either directly for the piece of conductor, or when the conductor is incorporated into part of a circuit that includes other components (for example purposes, capacitors or inductors). This increased ratio can yield a coil element or more generally an imaging coil that can receive/acquire electromagnetic signals with a higher Signal-to-Noise Ratio (SNR) than would be possible from an imaging coil of similar overall form factor constructed with metallic conductors only.

Similarly, the imaging coil element will also have a larger quality factor Q than would be possible with an imaging coil of similar form factor constructed with metallic conductors only. Variations within the scope of the invention of the specific forms and embodiments described herein can be determined from the teachings here by those skilled in the art, can be selected for specific imaging applications based on the optimal electrical properties for a particular application, or based on convenience or ease of construction, or a combination of these and/or similar other practical factors. Thus, according to the disclosed embodiments and corresponding description, carbon-based nanomaterial conductors can be constructed in a variety of geometric forms that possess minimal RF skin effects and can be incorporated into imaging coil elements with enhanced ratio of inductive reactance to resistance, together with suitable electronic circuitry to obtain high coil sensitivity over at least a portion of the entire volume of interest.

The larger quality factor values that can be obtained with imaging coils formed with shaped carbon nanomaterials can also mean that the signal bandwidth associated with these coils will be smaller or narrower. Thus relatively more signal can be received in a narrower bandwidth near the frequency of interest, and higher SNR values can be obtained than with conventional imaging coils constructed with metallic electrical conductors only. The narrower bandwidth also means that when used in transmit mode, the coils can transmit power more efficiently near a desired frequency of interest. Thus, for a given imaging RF pulse sequence, the transmit power requirements associated with an imaging coil of the present invention can be smaller than that of a conventional coil of similar form factor constructed with metallic electrical conductors only.

This decrease in required transmit power can be five per cent, ten per cent, or even range beyond fifty per cent in some cases. Since the transmit bandwidth can be smaller, the Specific Absorption Rate (SAR) of electromagnetic power absorption/deposition in tissue associated with a given RF transmit pulse can also be smaller. Thus transmit coils including formed carbon nanomaterial would be not only more efficient, but also would be safer to use in RF transmit mode for imaging a subject anatomy since the total RF power deposited in the subject's tissue would be smaller than for a conventional coil of similar form factor constructed with metallic electrical conductors only. For a given tissue type, for an imaging coil element of the present invention of known form factor, in RF transmit mode the decrease in SAR for a given RF pulse sequence can be five per cent, ten per cent, or even range beyond fifty per cent in some cases as compared to a conventional coil of similar form factor constructed with metallic electrical conductors only.

The imaging coil arrays of the present invention can be designed for use with a magnetic resonance imaging system where the spatial sensitivity profile associated with the array is recorded, for use with parallel imaging techniques such as Sensitivity Encoded (SENSE) imaging or other methods of accelerated imaging familiar to those skilled in the art. For example, an imaging coil element can be constructed using carbon-based nanomaterial conductors according to the teachings herein to be capable of operating in dual-tuned or multi-tuned fashion in order to receive RF signals from more than one type of atomic nucleus. For example, such an imaging coil element can be constructed to resonate at two frequencies for instance by employing dual tank circuits in suitable fashion or by controlling the tuning electronically through the use of voltages applied to suitable varactors, and a variety of other methods familiar to those skilled in the art.

Similarly, an imaging coil array can be constructed using carbon-based nanomaterial conductors according to the teachings herein with multiple independent imaging channels, such that at least two of these channels consist of shaped carbon nanomaterial imaging coil elements designed to resonate at different frequencies corresponding to different atomic nuclei, with at least one of these two imaging coil elements constructed using carbon-based nanomaterial conductors according to the teachings herein.

Furthermore while the specific forms of carbon-based nanomaterial discussed herein include single and multi-walled carbon nanotubes, buckypaper, carbon nanotube-infused polymers, or graphene, with possible incorporation into a polymeric matrix or other, possibly conducting, substrate, it is understood that the term carbon nanomaterial or carbon-based nanomaterial in the context of the imaging coil elements can include, without limitation, any of the above varieties of nano-structured carbon-based materials or to other generally similar forms and variations with generally similar charge transport characteristics.

Such embodiments and variations can apply to the case of either Radio Frequency (RF) signal reception or Radio Frequency (RF) signal transmission. As mentioned earlier, the range of radio frequencies where it may be advantageous to employ the present invention can lie, for illustrative purposes, in the approximate range of 3 MHz to 700 MHz. Likewise, for non-limiting illustrative purposes, the static magnetic field strength of the MRI scanner that interfaces with the imaging coil of the present invention can lie in the range 0.06 Tesla to 17 Tesla.

The carbon nanomaterial can be electrically joined to more conventional metallic junctions or circuit elements by any of several metallization methods familiar to those skilled in the art, some of which are described in the following. The ends of the nanomaterial conductor can be electroplated with copper, gold, or other metals, or electrically conducting silver paste can be applied to the ends. Electroplating processes, for instance, are well known in the art. As the silver paste (typically containing a relatively high proportion of silver particles in a resin) dries or cures, in some cases (depending on the type of resin used in the paste) at temperatures above normal room temperatures in an oven, the silver particles form a continuous matrix forming a connection with the carbon nanomaterial.

Alternatively, electrodes comprising materials such as palladium or platinum can be deposited at the ends of the nanomaterial conductor by a sputtering process or vapor deposition. With the forms of electrical connection described in the above, the ends of the nanomaterial conductor are effectively turned into metal-covered or metallic electrode ends that can then be directly soldered on to conventional metallic junctions or circuit elements (for example, capacitors, inductors, diodes, etc.) for incorporation of or joining to other circuitry.

A metallization length of between approximately 5 mm and 20 mm, and a metallization thickness of at least several microns, can be suitable in practice in order to yield good electrical connectivity and mechanical robustness in electrical connections (such as solder joints) between the nanomaterial conductor and metal conductors or other electrical components or circuit elements. These guidelines can help to set a range for process parameters (for example, current flow in an electroplating process) to generate the desired metallization length and thickness at the ends of the nanomaterial conductor.

For example, the metal-covered ends of the nanomaterial can be soldered or otherwise (for instance through the use of commercially available conducting paste or glue) electrically joined to an electrode pad, and the pad can then be used to connect to metallic junctions or circuit elements, depending on convenience of handling or forming connections. Similarly, the metal-covered ends of the nanomaterial can be soldered to a layer of metal or thin metal, or part of a fold of metal, or to the inside or outside of a tube of metal. In this manner electrically well-connected sandwich or other multilayer or generally hybrid conductor configurations employing the carbon nanomaterial and metal can be constructed.

These and related aspects are further clarified by means of references to exemplary embodiments shown in the Figures, as described below.

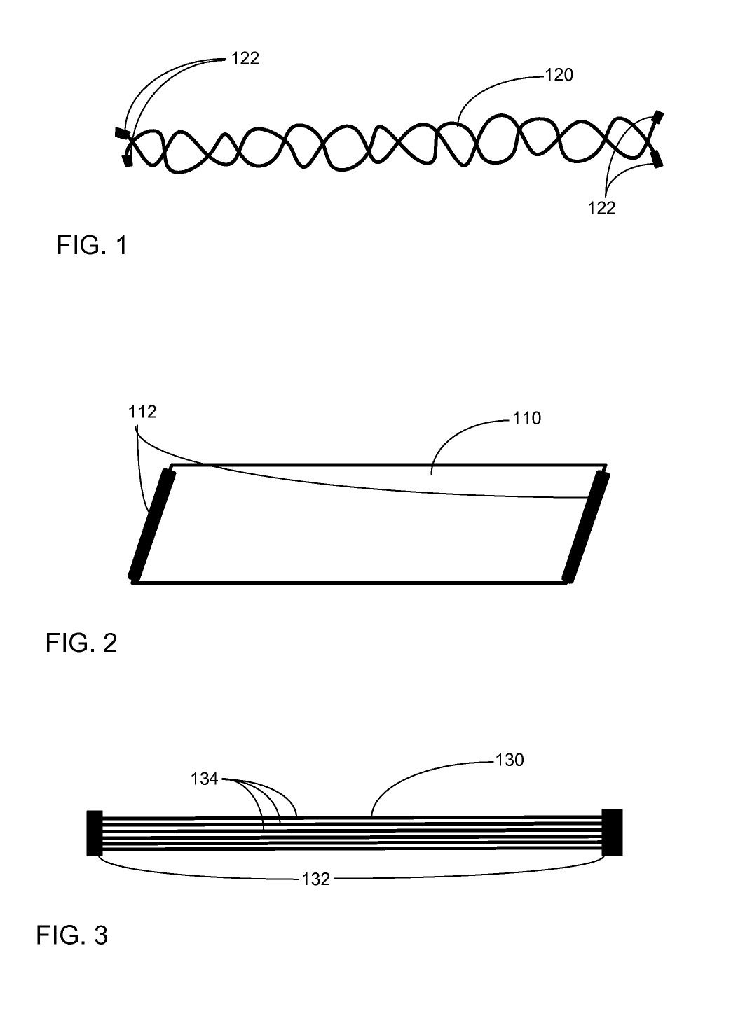

Turning now to FIG. 1, a nanomaterial conductor 120 is illustrated in the form of a twisted or braided thread or yarn shape and having metallized ends 122. Metallized ends 122 can be formed by any of the processes mentioned earlier, or by other processes familiar to those skilled in the art. Metallized ends 122 can be useful to form electrical junctions with other circuit elements by standard soldering methods. In similar manner, FIG. 2 shows a schematic illustration of a nanomaterial conductor 110 in the form of a ribbon-like geometry and having metallized ends 112. As shown in FIG. 3, composite nanomaterial conductor 130 can also be made to have metallized ends 132. Nanomaterial conductor 130 is shown in the form of a bundle of individual nanomaterial conductors 134, with the entire conductor structure having metallized ends 132.

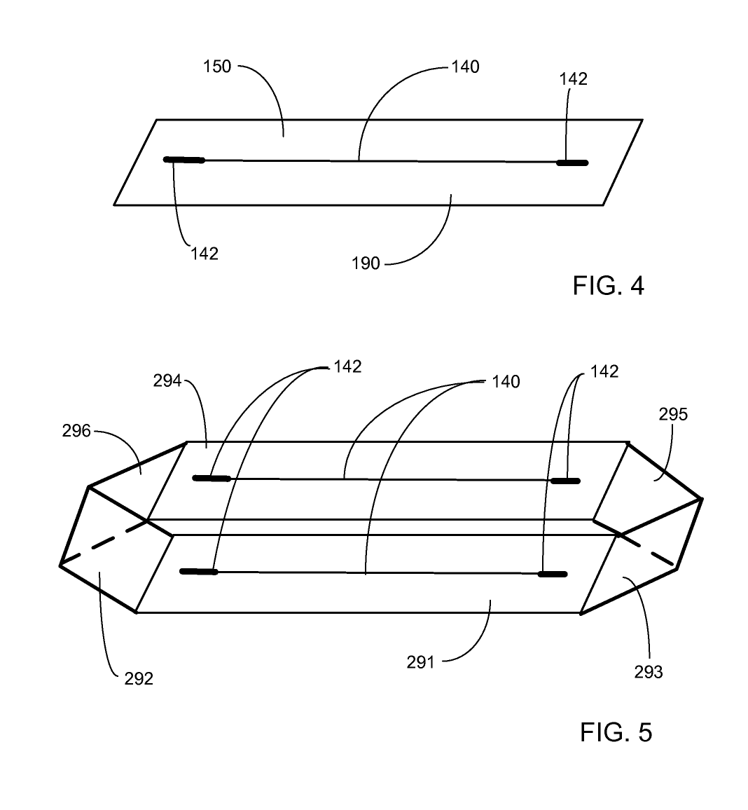

In FIG. 4, a schematic illustration of a hybrid conductor is shown in the form of nanomaterial conductor 140 with metallized ends 142 laid on metallic conductor 150 and with metalized ends 142 attached to metallic conductor 150. In each of the illustrated Figures, nanomaterial conductor 140 can itself be any of the structures referred to in the descriptions above, such as a ribbon, yarn, thread, rope, or a composite/bundle structure, or any other variations. FIG. 5 illustrates a composite hybrid conductor in the form of two layers of a hybrid conductor, each having shaped nanomaterial conductor 140 with metallized ends 142 each attached to one of metallic conductors 291, 294. In the figure, the top layer includes nanomaterial conductor 140 laid onto metallic conductor 291 and with metallized ends 142 attached to the latter, and the bottom layer includes nanomaterial conductor 140 laid onto metallic conductor 294 and with metallized ends 142 attached to the latter. In some embodiments, nanomaterials conductor 140 may be attached directly to circuitry of an imaging machine without the additional parallel electrical conductor, represented, for example, as metallic conductor 150, 294, 390, 490, etc.

Metallic conductor 291 can be electrically joined at its ends 292, 293 to metallic conductor 294 at its ends 295, 296, respectively. While FIG. 5, for purposes of clarity, shows only two separated hybrid layers that are joined at the ends, it is possible to generalize this arrangement to incorporate a multiplicity of such hybrid layers, as desired for a given coil array design. Furthermore the separation between layers can be quite small in practice. The nanomaterial conductor 140 can itself be any of the structures referred to in the descriptions here, such as a ribbon, yarn, thread, rope, or a composite/bundle structure, or any other variations.

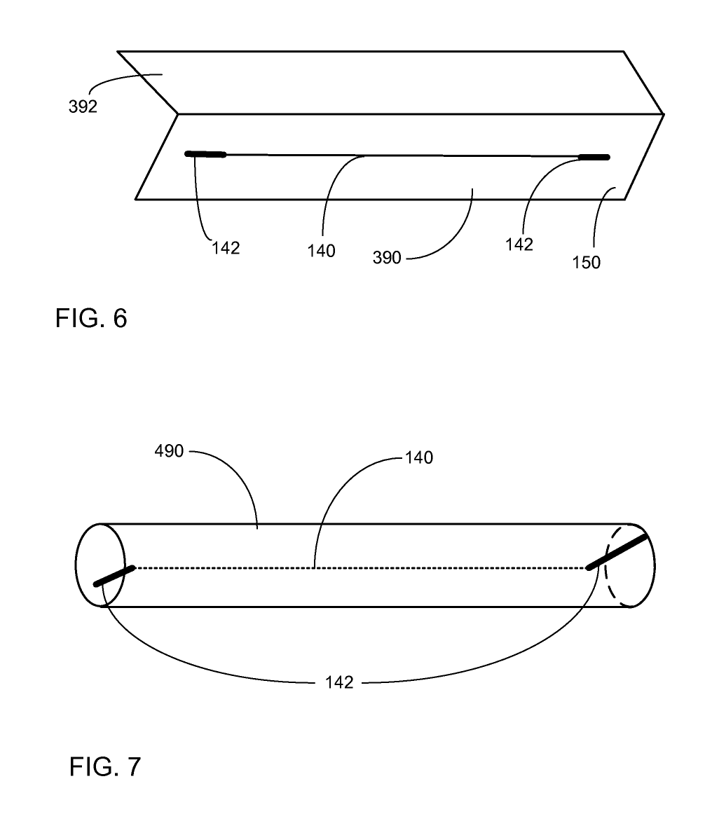

FIG. 6 illustrates a nanomaterial conductor 140 with metallized ends 142 laid on metallic conductor 390 that is folded to have top surface 392. Metallized ends 140 can be electrically joined to metallic conductor 390. As illustrated, nanomaterial conductor 140 can be laid on and attached to metallic conductor 390 with fold 392. While only a two-folded structure with single nanomaterial conductor 140 is shown in FIG. 6 for purposes of clarity, a multiplicity of combinations of folds and nanomaterial conductors can be used, as convenient for the application. Such variations are within the scope of the present invention.

FIG. 7 illustrates a nanomaterial conductor 140 with metallized ends 142 placed within metallic conductor 490 in the form of a hollow metallic tube, with ends 142 attached to metallic tube 490.

The nanomaterial conductors as described in the foregoing in any of their various embodiments, including their hybrid forms, can be formed into resonant RF (Radio Frequency) tuned circuits to optimize signal reception at or near a desired tuning frequency. As is familiar to those skilled in the art, such a resonant circuit can generally be formed by attaching other circuit elements, such as for example capacitors and inductors, to build a resonant structure that generally includes one or more resonant loops or that incorporates a multitude of loops in a patterned arrangement, constituting an imaging coil element for reception and/or transmission of electromagnetic signals for Magnetic Resonance imaging applications. As is known to practitioners of the art, tuning and matching circuitry is usually also incorporated into the construction of an imaging coil element in order to create a resonant structure at or near a desired operating frequency relevant to the application. In the case of an imaging coil element used for signal reception, blocking circuitry to detune the coil during the RF transmit phase is incorporated in active or passive forms or both usually by the use of appropriate diodes such as PIN diodes.

In the following and in the foregoing, while the term “imaging coil element” usually refers to a shaped carbon nanomaterial conductor, or a hybrid conductor formed into a given geometrical shape and then attached to a circuit board/electronic components for tuning to create an electrically resonant structure, it is also sometimes used to refer to a single coil or channel that is part of a multi-element or multi-channel array imaging coil. The appropriate meaning will be clear from the context.

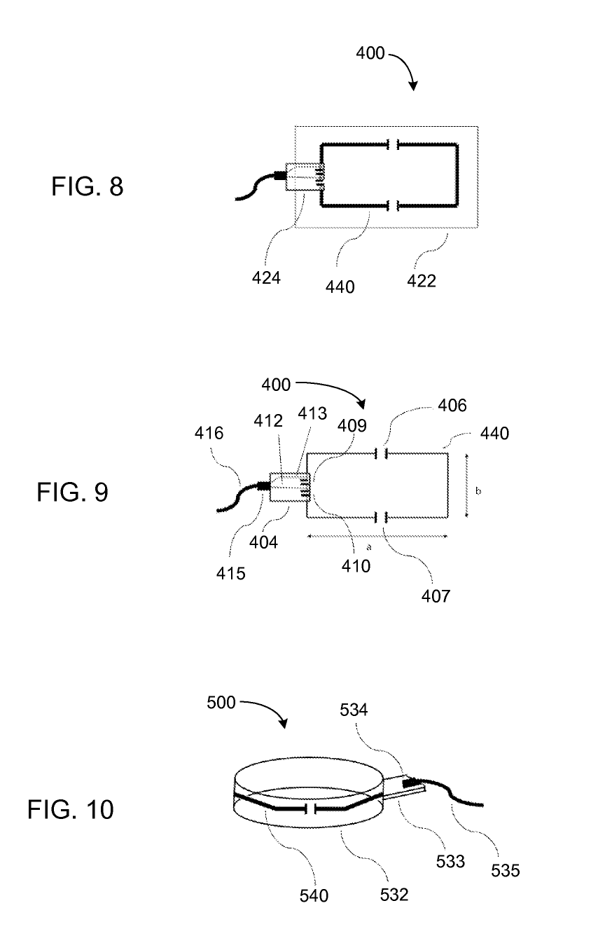

As an example of construction of a shaped carbon nanomaterial imaging coil, FIG. 8 schematically shows an imaging coil element 400 in the form of a generally rectangular loop, with shaped carbon nanomaterial conductor 440 of imaging coil element 400 constructed in a manner conforming to at least one of the conductor forms discussed above. Imaging coil element 440 can be mounted (by means of adhesives or other attachment methods known to those skilled in the art) on substrate or base 422 (possibly, for example purposes, in the form of a plastic or polymeric sheet or thin block) and connected to a circuit board 424, possibly also attached to the base or substrate.

FIG. 9 illustrates imaging coil 400 in further detail. In FIG. 9, imaging coil element 400 has a rectangular form with rectangle dimensions a and b (together describing the form factor) and can further include capacitors 406 and 407 connected in series with shaped carbon nanomaterial conductor 440. As illustrated, capacitors 406, 407 can be inserted into gaps between segments of conductor 440. Capacitors 406 and 407 can serve to reduce electric fields around the coil and thence lead to reduced effective electrical resistance associated with the coil. Although two capacitors are shown in this figure, the number of such capacitors in a given imaging coil of the present invention can also be larger or smaller depending on desired performance. Since shaped carbon nanomaterial conductor 400 includes metalized ends (as described above), each capacitor can be directly soldered to conductor 440 to ensure good electrical connectivity.

Imaging coil element 400 can be connected to circuit board 404. Circuit board 404 can include components for tuning the coil to a desired resonant frequency and for matching the coil to a desired impedance value. Capacitors 410 and 409 respectively are shown schematically on circuit board 404. Also shown on the circuit board are electrical traces 412 and 413. An electrical board-mount RF connector 415 (such as, for example, an SMA connector) can attach to board 404, and coaxial cable 416 can connect the circuit board 404. Coaxial cable 416 can carry received RF signals back to an MRI scanner possibly by way of a preamplifier (not shown) for early-stage signal amplification, as is known to those skilled in the art. Circuit board 404 can further include other electrical components (not shown), such as other capacitors and inductors and PIN diodes for example for purposes of coil detuning during MRI system transmit, as is well known in the art and associated literature.

FIG. 10 illustrates an embodiment of imaging coil 500 having a generally circular geometry, and showing various details of the construction. The imaging coil element 540 can include one or more nanomaterial conductor constructed according to any of the forms described above, and can be wound around a generally circular substrate ring 532. Substrate ring 532 can be constructed, for example, of plastic or polymeric material, or any other suitable material. Imaging coil element 540 can be attached at its ends to circuit board 533 incorporating circuit elements (such as capacitors, inductors, diodes) for tuning, impedance matching and RF transmit detuning. Thus imaging coil 500 is tuned to a desired resonant frequency. Circuit board connector 534 attached to the board connects to a coaxial cable 535, with the coaxial cable carrying received RF signals to an MRI scanner with possible routing through a preamplifier for early-stage signal amplification.

A resonant structure in the form of a multitude of distinct imaging coil elements, in some cases possibly including suitable circuit interconnections that may be needed to reduce inter-element electromagnetic coupling, can also be built in order to receive signals in a form known in the literature as a phased array construction. The electronic circuitry associated with such an array imaging coil can include elements such as low impedance preamplifiers, which are often used to decouple or reduce the coupling between imaging coil elements in the array imaging coil. The methodologies for building such phased array configurations are known to those skilled in the art. Such multiple-element phased array constructions are useful in the acquisition of signals for parallel imaging, which can result in faster scan times, improved Signal-to-Noise Ratio within a region of interest, or a combination of these enhancements. Likewise, the imaging coil can include circuit elements or sub-circuits that are intended to block or decouple the receive coil elements from the RF transmit pulse during the transmit phase of the imaging sequence.

In some embodiments, the RF coils of the present invention can be capable of either one of, or both of, transmission and reception of electromagnetic signals. For instance, in the case of RF pulse transmission, associated electronic circuitry including T/R (Transmit/Receive) switches would be incorporated into the signal path as is well known to those skilled in the art. Since the nanomaterial-based constructions and embodiments described here can generally be made to yield a larger ratio of inductive reactance to resistance than would be possible for an electrical conductor constructed of metal alone, either directly for the piece of conductor, or when the conductor is incorporated into part of a resonant circuit or imaging coil element that includes electronic components such as capacitors, inductors, etc., the imaging coil of the present invention will correspondingly receive signals and generate images with a larger Signal-to-Noise Ratio (SNR) than would be possible from an imaging coil of similar form factor constructed with metallic conductors only.

In similar manner the imaging coil element disclosed herein will also have a larger quality factor Q than would be possible with an imaging coil of similar form factor constructed with metallic conductors only. In the case where the imaging coil and associated circuitry is built to support transmission of electromagnetic signals, the imaging coil will correspondingly be able to transmit electromagnetic signals more efficiently, with less loss, than would be possible from an imaging coil with similar form factor constructed with metallic conductors only.

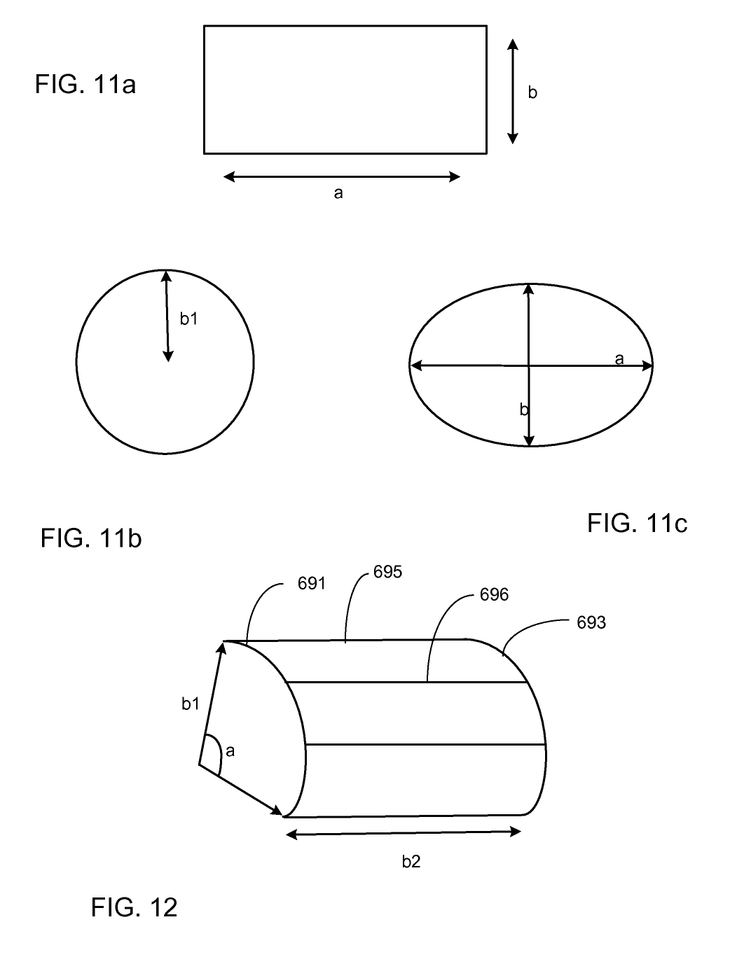

Examples of imaging coil element form factors are provided in FIGS. 11a-12. For purposes of clarity in these figures, detailed coil constructions including circuit boards or breaks in the nanomaterial conductor for capacitors are not explicitly shown; rather the focus is on the overall geometry or shape of the coil, as will be clear. A coil element in the form of a rectangular loop with sides of length a and b (similar to that of FIGS. 8 and 9) is shown schematically in FIG. 11a. In this case these dimensions together define the overall form factor. A coil element in the form of a circular loop of radius b1 is shown schematically in FIG. 11b5; in this case the overall form factor is defined by this single number b1. The schematic illustration in FIG. 11c shows a coil element of elliptical configuration, with ellipse major and minor axes of lengths a and b respectively. In this case the overall form factor is defined by the set (a, b) with the associated geometrical meaning of each dimension in this set.

FIG. 12 shows an example of an imaging coil element of more complex geometry, schematically depicted in that figure in the form comprising arcuate conductors 691 and 693 of radius b1 each with an angular extent of a as shown in the figure, as well as generally straight conductors such as 695 and 696 of length b2. In this case the set of dimensions (b1, b2, a), which includes both linear dimensions b1 and b2 and angular dimension a, and their associated geometrical meanings define the overall form factor.

It is worth noting again that the depictions in FIGS. 11a-12 explaining overall form factor are schematic illustrations intended to be as such for purposes of clarity, and details such as capacitors distributed along the length of the coil, gaps in the conductor where other electrical or electronic components or circuitry may be attached, circuit boards, and the like are not explicitly shown. The examples of geometries and form factors shown in these figures are provided as examples for illustrative purposes only and any variations or alternative coil element geometries can also, without any limitation, be described in terms of a form factor similar to the exemplar illustrations provided here. Thus in general the form factor of a coil element is taken to be a set of generalized dimensional numbers that describe overall geometry, for example including both linear and angular dimensions, as well as other similar geometrical quantities such as for instance solid angles where appropriate, together with their associated geometrical meanings that in total describe the overall size and shape of the coil element.

Tuning circuitry can be used to tune the imaging coil of the present invention to preferentially receive RF electrical signals in a relatively narrow bandwidth around the center frequency associated with the scanner magnet, and to match the effective coil impedance to a specified/desired preamplifier impedance for optimal signal transfer to the scanner. The tuning may be accomplished by any known tuning method. The sharpness of the tuning is measured by the Quality Factor Q, defined for the bare coil to be the ratio (L/R) of the inductive reactance to the resistance associated with the coil (generally while in interaction with the subject tissue). A sharper tuning or higher Q factor leads to relatively more signal energy captured by the coil compared to the noise picked up by the coil at the same time. Considering a nanomaterial coil with a Quality Factor value Qₙ, one can define a corresponding Quality Factor Qₛ for a standard coil with a completely metallic conducting element (for example made of copper) of closely identical form factor or overall dimensions to the nanomaterial coil. By using a sufficient quantity of nanomaterial so as to provide an appropriate cross section for charge transport, a nanomaterial coil can be built so as to possess a ratio Qₙ/Qₛ that can be at least 1.05, extending to at least 1.1, and even at least 1.2. The ratio reflects quality gains that can be more than 20%.

In order to prevent signal pickup by the coil during system transmit mode, PIN diodes may be included in the circuitry at various locations, either as part of a board for the tuning circuitry for the coil, or at the breaks in the conducting element. In some cases the PIN diodes can be actively turned on by application of a suitable bias voltage that can then activate circuitry that serves to block signals in the coil.

In addition to any previously indicated modification, numerous other variations and alternative arrangements can be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use can be made without departing from the principles and concepts set forth herein. Also, as used herein, examples are meant to be illustrative only and should not be construed to be limiting in any manner.

1. An imaging coil element for magnetic resonance imaging, the imaging coil element comprising:
at least one electrical conductor formed from shaped carbon-based nanomaterial, the carbon-based nanomaterial conductor having a ratio of electrical inductive reactance to electrical resistance, over a range of frequencies, that is larger than that of a similarly dimensioned electrical conductor constructed only of metal; and
a connector coupled to the first electrical conductor for functionally connecting the imaging coil element to electronic circuitry connecting to a magnetic resonance imaging system.

2. The imaging coil element of claim 1, wherein the range of radio frequencies is between about 3 MHz and 700 MHz.

3. The imaging coil element of claim 1, wherein the carbon-based nanomaterial includes carbon nanotubes.

4. The imaging coil element of claim 3, wherein the carbon-based nanomaterial is formed into buckypaper.

5. The imaging coil element of claim 1, wherein the carbon-based nanomaterial is graphene.

6. The imaging coil element of claim 1, wherein the carbon-based nanomaterial is formed in a ribbon-like shape.

7. The imaging coil element of claim 1, wherein the carbon-based nanomaterial is formed in a string-like shape.

8. The imaging coil element of claim 1, wherein the carbon-based nanomaterial is formed in a yarn-like shape.

9. The imaging coil element of claim 1, wherein the imaging coil element is one element in an imaging coil array used for at least one of transmission or reception of radio frequency signals.

10. The imaging coil element of claim 1, wherein the at least one conductor has metalized ends, and wherein at least one of the metalized ends includes at least one electrical connection between the connector and the at least one conductor.

11. The imaging coil element of claim 1, wherein the imaging coil element is connectable to electronic tuning and matching circuitry to create an electrically resonant structure near a frequency of interest.

12. The imaging coil element of claim 11, wherein the electronic tuning and matching circuitry includes a preamplifier for augmenting signal gain.

13. An imaging coil for an MRI system, the imaging coil comprising:
a plurality of imaging coil elements, at least one of the plurality of imaging coil elements being formed from shaped carbon-based nanomaterial,
in each of the at least one imaging coil element formed from carbon-based nanomaterial, the nanomaterial having a ratio of electrical inductive reactance to electrical resistance for the imaging coil element, over a range of frequencies, that is larger than that of a similarly dimensioned imaging coil element constructed only of metal.

14. The imaging coil of claim 13, wherein the shape of the carbon-based nanomaterial in at least one of the imaging coil elements formed from carbon-based nanomaterial is selected from:
a yarn-like shape;
a ribbon-like shape; and
a string-like shape.

15. The imaging coil of claim 13, wherein the carbon-based nanomaterial in the at least one imaging coil element formed from carbon-based nanomaterial is structured as one of:
carbon nanotubes;
buckypaper; and
graphene.

16. The imaging coil of claim 13, each of the imaging coil elements including a metal conducting connector deposited on at least one end of each of the imaging coil elements for electrically coupling the imaging coil to an MRI system.

17. The imaging coil of claim 13, wherein the imaging coil has a known spatial signal sensitivity profile and is adapted to be utilized in the image reconstruction process with data from radio frequency signals received by the imaging coil to reconstruct an anatomical image of a desired region of interest in a subject being imaged.

18. The imaging coil of claim 13, wherein the at least one imaging coil element formed from carbon-based nanomaterial has a larger quality factor than that of a coil element of similar form factor constructed with only metallic electrical conductors.

19. The imaging coil of claim 13, wherein the transmit power requirement for a given radio frequency pulse sequence for the at least one imaging coil element formed from carbon-based nanomaterial while transmitting radio frequency energy is at least ten per cent smaller than the transmit power requirement for the same radio frequency pulse sequence for an imaging coil element of similar form factor formed with only metallic electrical conductors.

20. The imaging coil of claim 13, wherein while the at least one imaging coil element formed from carbon-based nanomaterial is transmitting radio frequency energy, the Specific Absorption Rate for a given tissue type and given radio frequency pulse sequence is at least ten per cent smaller than the Specific Absorption Rate for the same tissue type and radio frequency pulse sequence for an imaging coil element of similar form factor formed with only metallic electrical conductors.
